(19) United States
(12) Patent Application Publication
(10) Pub. No.: US 2026/0052633 A1
(43) Pub. Date: Feb. 19, 2026

(54) Localized Soldering U&C Shape with Metal Pin Design

(71) Applicant: Apple Inc., Cupertino, CA (US)

(72) Inventors: Tiexuan Wang, Shanghai (CN); Minh C. Dang, San Jose, CA (US); Yajun Lu, Shanghai (CN); Wei Wu, Suzhou (CN); Yong Gang Li, Suzhou (CN)

(21) Appl. No.: 18/802,340

(22) Filed: Aug. 13, 2024

(51) Int. Cl. H05K 3/34; H05K 1/18

(52) U.S. Cl. CPC H05K 3/3426; H05K 1/181; H05K 1/189; H05K 3/3468; H05K 2201/09072; H05K 2201/0919; H05K 2201/0939; H05K 2201/09481; H05K 2201/10037; H05K 2201/10121; H05K 2201/10303; H05K 2201/10545; H05K 2201/10628; H05K 2201/10704; H05K 2201/10757; H05K 2201/10931

(57) ABSTRACT

Electronic assemblies and methods of joining components are described. The electronic assemblies may include a bottom component with one or more pins mounted over a top component with one or more recesses, where the pins of the bottom component align with the recesses of the top component. Further, the recesses and pins may be structured so that the shape of the pins matches the shape of the recesses, and that the recesses at least partially surround the pins.

### BACKGROUND

### Field

Embodiments described herein relate to microelectronic assembly.

### Background Information

The current market demand for portable and mobile electronic devices such as mobile phones, personal digital assistants (PDAs), digital cameras, portable players, gaming, wearables, and other mobile devices requires the integration of more performance and features into increasingly smaller spaces. Furthermore, additional numbers of components such as sensors, light sources, cameras, antennae, etc. are being integrated into increasingly small form factors within the electronic devices.

### SUMMARY

Electronic assemblies and methods of joining components are described. The electronic assemblies may include a top component mounted over a bottom component bonded by a solder joint. In an embodiment, the bottom component may include one or more pins and the top component may include one or more recesses, where the pins of the bottom component align with the recesses of the top component. In an embodiment, a shape or contour of the pins of the bottom sufficiently matches a shape or contour of the recesses of the top component so that the recesses may receive the pins. Further, a size of the pins (e.g., diameter, width, etc.) may be less than the size of the recesses so that the recesses at least partially surround the pins. In an embodiment, a top portion of the pins may be bent or curved over a top surface of the top component to prevent solder material from flowing down through the recesses.

### BRIEF DESCRIPTION OF THE DRAWINGS

FIGS. 1A-1B is a perspective view illustration of an electronic assembly in accordance with embodiments.

FIG. 2A is a perspective view illustration of a circular cylindrical pin in accordance with embodiments.

FIG. 2B is a perspective view illustration of a rectangular pin in accordance with embodiments.

FIG. 2C is a perspective view illustration of an elongated cylindrical pin in accordance with embodiments.

FIG. 2D is a perspective view illustration of an elongated rectangular pin with a curved top portion in accordance with embodiments.

FIG. 2E is a perspective view illustration of a partial cylindrical pin in accordance with embodiments.

FIG. 2F is a perspective view illustration of a partial elongated cylindrical pin in accordance with embodiments.

FIG. 3A is a top view schematic illustration of a circular cylindrical pin and a c-shaped recess in accordance with embodiments.

FIG. 3B is a top view schematic illustration of an elongated cylindrical pin and a u-shaped recess in accordance with embodiments.

FIG. 3C is a top view schematic illustration of an elongated rectangular pin and a u-shaped recess in accordance with embodiments.

FIG. 3D is a perspective view illustration of a liner layer formed within a c-shaped recess over a bottom component in accordance with an embodiment.

FIG. 3E is a perspective view illustration of a liner layer formed within a c-shaped recess over a bottom component with a surface plated top surface in accordance with an embodiment.

FIG. 4A is a schematic cross-sectional side view illustration of an electronic assembly including pins and solder joints in accordance with embodiments.

FIG. 4B is a schematic cross-sectional side view illustration of an electronic assembly including pins with a bent top portion and solder joints in accordance with embodiments.

FIG. 4C is a schematic cross-sectional side view illustration of an electronic assembly including pins with bent top and bottom portions and solder joints in accordance with embodiments.

FIG. 5 is a flow chart of a method for joining a bottom component and a top component in accordance with embodiments.

FIGS. 6A-6C are schematic cross-sectional side view illustrations of a method for joining a bottom component and a top component in accordance with embodiments.

### DETAILED DESCRIPTION

It has been observed that assembling various packages, components, PCBs, etc. to meet the increasingly small form factors within electronic devices may not provide enough space for the inspection of such assemblies. For example, during Final Assembly, Test and Pack (“FATP”) processes, there may be very limited space to conduct solder quality inspection. In such instances, the solder joint may not even be visible when positioned in the final assembly.

Embodiments described structures and methods for solder bonding multiple components of an electronic assembly. In accordance with embodiments, an electronic assembly may include a top component mounted over a bottom component, where one or more pins that extend vertically from the bottom component align with one or more recesses that are located within outer perimeter lateral edges of the top component. In an embodiment, the shape or contour of the pins (e.g., cylindrical, rectangular, elongated cylinder, etc.) may sufficiently match the shape and contour of the recesses (e.g., c-shaped, u-shaped, etc.) so that the pins may be received by the recesses, where a solder joint may provide an electrical and mechanical connection between the pins and recesses. In this way, with the solder joint located on a top surface of the top component, the electronic assembly may be more readily accessible and visible when conducting solder quality inspections during FATP processes.

In various embodiments, description is made with reference to figures. However, certain embodiments may be practiced without one or more of these specific details, or in combination with other known methods and configurations. In the following description, numerous specific details are set forth, such as specific configurations, dimensions and processes, etc., in order to provide a thorough understanding of the embodiments. In other instances, well-known processes and manufacturing techniques have not been described in particular detail in order to not unnecessarily obscure the embodiments. Reference throughout this specification to “one embodiment” means that a particular feature, structure, configuration, or characteristic described in connection with the embodiment is included in at least one embodiment. Thus, the appearances of the phrase “in one embodiment” in various places throughout this specification are not necessarily referring to the same embodiment. Furthermore, the particular features, structures, configurations, or characteristics may be combined in any suitable manner in one or more embodiments.

The terms “over”, “span”, “to”, “between”, and “on” as used herein may refer to a relative position of one layer with respect to other layers. One layer “over”, or “on” another layer or bonded “to” or in “contact” with another layer may be directly in contact with the other layer or may have one or more intervening layers. One layer “between” layers may be directly in contact with the layers or may have one or more intervening layers.

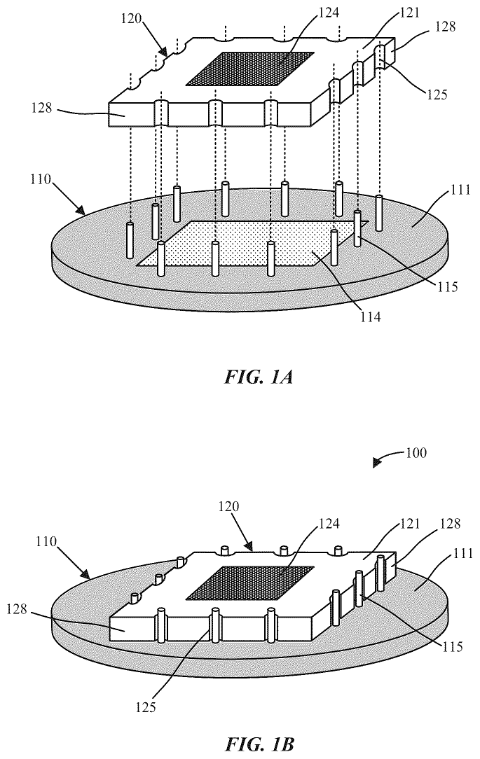

Referring now to FIGS. 1A-1B, perspective view illustrations of an electronic assembly in accordance with embodiments are shown. Electronic assembly 100 may be implemented as a component of a wearable device (e.g., smartwatch, earbud, etc.) as well as other electronic devices. Further, electronic assembly 100 may include bottom component 110 and top component 120, where top component 120 may be mounted over bottom component 110, as illustrated in the example of FIG. 1B. In embodiments, the bottom component may be an electronic component (e.g., optical module, chip driver, etc.). In addition, the bottom component may include one or more pins that extend vertically from its top surface. For example, in reference to FIG. 1A, bottom component 110 includes pins 115 that extend vertically from top surface 111 of bottom component 110, where pins 115 surround optical component 114. In the example of FIG. 1A, bottom component 110 includes 12 pins (three pins on each side of optical component 114). In other embodiments, the number of pins may vary (e.g., singular pin, multiple pins, etc.), where any number of pins may be located on any number of sides of a component.

In further reference to FIGS. 1A-1B, electronic assembly 100 may also include top component 120 mounted over bottom component 110. In embodiments, top component 120 may be a printed circuit board (e.g., rigid, flexible, etc.). In addition, top component 120 may be connected to an electric module (e.g., battery, etc.), such as electric module 124 in FIGS. 1A-1B. Further, top component 120 may include one or more recesses located within outer perimeter lateral edges of top component 120 to receive the one or more pins of bottom component 110. In this way, electronic assembly 100 exhibits a male-female connector relationship in that the one or more pins of bottom component 110 may be received by the one or more recesses of top component 120. Further, the one or more recesses may be through-hole pads (e.g., plated, non-plated, etc.) or side recesses into the outer edges of top component 120, where the through-hole pads or side recesses may only include a partial hole (e.g., half hole, etc.) due to the location of the one or more recesses within perimeter lateral edges of top component 120. For example, in reference to FIGS. 1A-1B, top component 120 includes electric module 124, and recesses 125 located within outer perimeter lateral edges 128 of top component 120. In further reference to FIGS. 1A-1B, bottom component 110 and top component 120 may be structured so that the one or more pins of bottom component 110 vertically align with the one or more recesses of top component 120 and protrude above top surface 121 of top component 120.

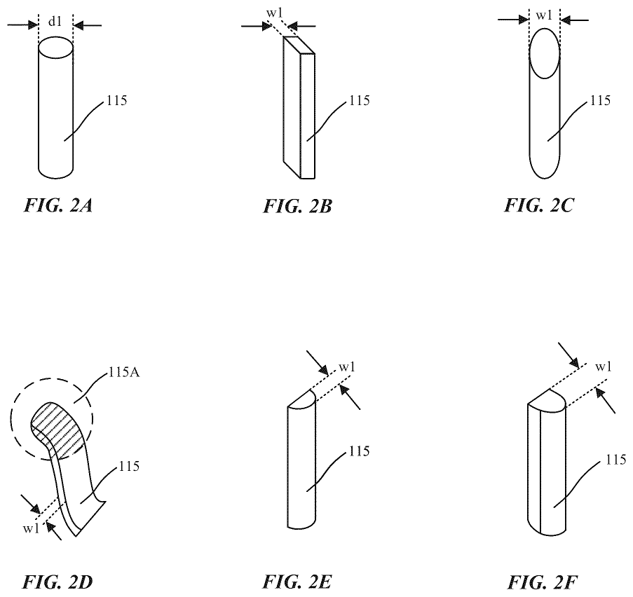

Referring now to FIGS. 2A-2F, a perspective view illustration of one or more pins in accordance with embodiments is shown. The one or more pins of bottom component 110 may be of any number, shape, contour, or size. In embodiments, the shape or contour of the one or more pins may vary and may include circular shapes, rectangular shapes, elliptical shapes, as well as other types of shapes or variations on such shapes (e.g., circular-like shapes, rectangular-like shapes, elliptical-like shapes, etc.). For example, pin 115 in FIG. 2A is circular cylindrical, whereas pin 115 in FIG. 2B is rectangular. In some embodiments, the one or more pins may include an elongated or oblong variation of a typical shape. For example, in FIG. 2C, pin 115 is an oblong variation of the circular cylinder in FIG. 2A, so that pin 115 in FIG. 2C represents an elliptic cylinder. In other embodiments, a portion of the one or more pins (e.g., top portion, bottom portion, etc.) may be bent or curved where, for example, a top portion of the one or more pins bends or curves over the top surface of the top component. For example, in FIG. 2D, pin 115 is an oblong variation of the rectangular pin in FIG. 2B, where the pin further includes a top portion 115A that is curved or bent. Further, the one or more pins may be composed of metal, such as copper, that include a coating or plating to protect the copper from oxidation and ensure solderability and bondability with other components (e.g., electroless nickel immersion gold plating (“ENIG”), tin coating, etc.). In other embodiments still, the one or more pins may be structured to include variations of or alterations to the one or more pins described to better conform to the contour or shape of the one or more recesses. For example, pins 115 may be structured to include a partial cylinder or c-shaped pin as illustrated in FIG. 2E, a partial elongated cylinder or u-shaped pin as illustrated in FIG. 2F, etc. It should be noted that the pin shapes or contours described here are merely representative, not exhaustive, and that other pin shapes and contours are contemplated.

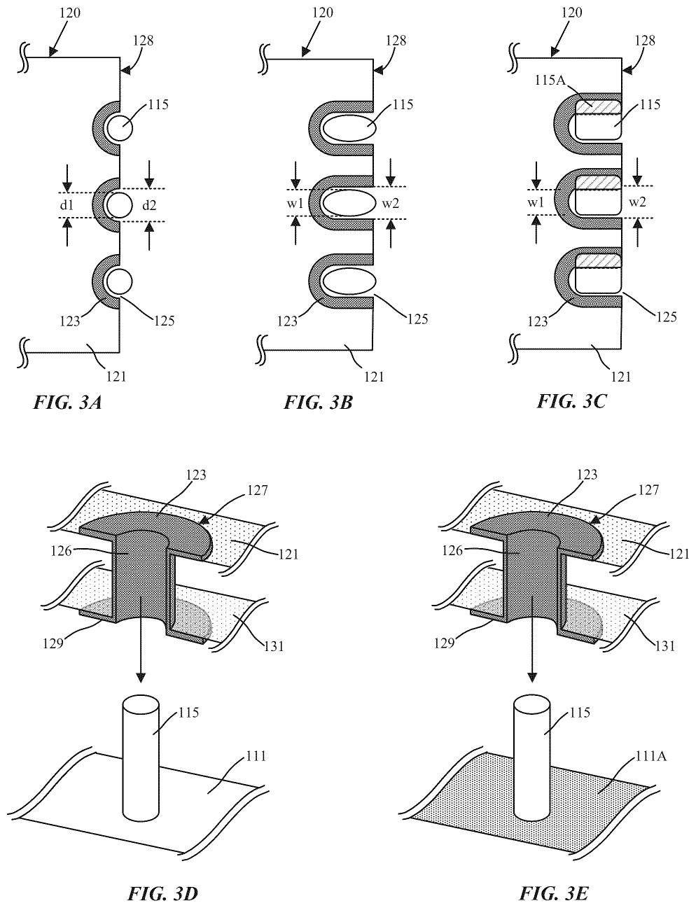

Referring now to FIGS. 3A-3E, a top view schematic illustration of one or more pins aligned with one or more recesses in accordance with embodiments is shown. In embodiments, the recesses and/or pins may be structured so that a recess contour or shape of the one or more recesses matches or sufficiently matches a pin contour or shape of the one or more pins so that the pins may be received by the recesses. Further, the recesses and/or pins may be sized so that the one or more recesses at least partially surrounds the one or more pins. For example, in FIG. 3A, the contour or shape of recess 125 is “c-shaped” in that recess 125 is a circular arc or circular-like arc that forms a half circle. Further, the contour or shape of pin 115 is a circular cylinder or circular-like cylinder similar to the example of FIG. 2A. As such, the c-shaped contour of recess 125 sufficiently matches the shape of pin 115. In addition, the diameter, d1, of pin 115 is less than the diameter, d2, of recess 125 so that recess 125 may at least partially surround pin 115 in FIG. 3A. In the example of FIG. 3B, the contour or shape of recess 125 is “u-shaped” in that recess 125 is an elongated circular arc or circular-like arc that forms a partial stadium or “pill” shape. Further, the contour or shape of pin 115 is an elongated circular cylinder or elliptic-like cylinder similar to the example of FIG. 2C. As such, the u-shaped contour of recess 125 sufficiently matches the shape of pin 115. In addition, the width, w1, of pin 115 is less than the width, w2, of recess 125 so that recess 125 may at least partially surround pin 115 in FIG. 3B. Similarly, the rectangular shaped pin of FIG. 2B can be inserted into the recess 125 of FIG. 3B. In the example of FIG. 3C, the contour or shape of recess 125 is also “u-shaped” in that recess 125 is an elongated circular arc or circular-like arc that forms a partial stadium or “pill” shape. Further, the contour or shape of pin 115 is an elongated or oblong rectangle or rectangle-like shape similar to the example of FIG. 2D. As such, the u-shaped contour of recess 125 sufficiently matches the shape of pin 115. In addition, the width, w1, of pin 115 is less than the width, w2, of recess 125 so that recess 125 may at least partially surround pin 115 in FIG. 3C, where a top portion 115A of pin 115 curves or bends directly over a top surface 121 of top component 120 (described in further detail below). The bend could be a variety of directions, orthogonal to the outer perimeter lateral edge 128, or parallel to the outer perimeter lateral edge 128 as shown in FIG. 3C. It should also be noted that the pins and recesses are not required to match exactly and that the pins and recesses may match sufficiently so that the recesses may receive the pins, such as the example of FIG. 3B where the u-shaped or stadium-like recesses sufficiently match the elliptic-like pins to receive them, or the example of FIG. 3C where the u-shaped or stadium-like recesses sufficiently match the rectangular-like pins to receive them.

Further, in the examples of FIGS. 3A-3E, and as shown in FIGS. 3D-3E, a metal liner layer 127 (e.g., plated layer(s) of copper, nickel, gold, tin, etc.) can be formed along the top surface 121 of top component 120 along the recess sidewalls of top component 120, and/or bottom surface 131 of the top component. For example, the metal liner layer 127 can include a top pad 123 along the top surface 121 of the top component, an edge sidewall liner 126 portion along the edge recess sidewalls, and optionally a bottom pad 129 along the bottom surface 131 of the top component, where bottom pad 129 may contact top surface 111 of bottom component 110 as illustrated in FIG. 3D. In some embodiments, top surface 111 of bottom component 110 (or at least a portion of top surface 111 of bottom component 110) may include metal surface plating (e.g., Au surface plating, etc.) such as metal surface plating 111A illustrated in FIG. 3E. The metal liner layer may facilitate making electrical connection with the pins once soldered. Furthermore, the top pad 123 can be shaped to provide a bonding surface for the solder, and may be shaped to receive top portion 115A of the pins that bent (and span/extend) directly over the top surface 121 of the top component. In the example illustrated in FIG. 3C the area of the top pad 123 that receives the top portion 115A of the pin can be wider than other areas of the top pad around the recess 125, though this is not required.

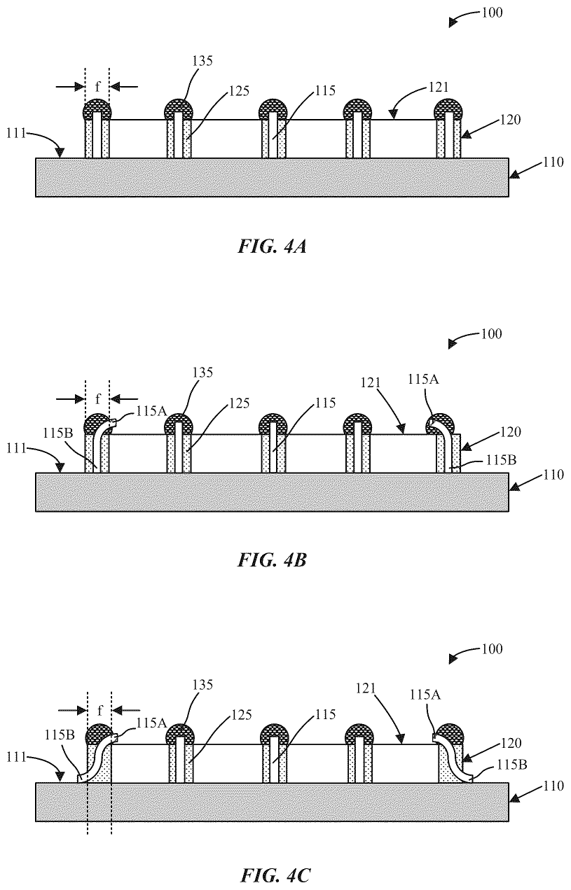

Referring now to FIGS. 4A-4C, schematic cross-sectional side view illustrations of an electronic assembly with solder joints in accordance with embodiments are shown. In embodiments, electronic assembly 100 may include solder joints to create a mechanical and electrical connection between the one or more pins of bottom component 110 and the one or more recesses of top component 120. The solder joints may be formed by any soldering process. In an embodiment, the solder joints may be formed by a laser soldering process in which a solder material (e.g., tin/lead, tin-zinc, etc.) may be deposited on top surface 121 of top component 120 where the pins and recesses meet, melted by a heat source (e.g., laser light), and then solidified after removal of the heat source to form the solder joint. In this way, where the solder joints are located on a top surface of the top component and therefore visible from the top or side, the solder joints may be more readily accessible for soldering quality inspection during a Final Assembly, Test and Pack (“FATP”) process.

In further reference to FIGS. 4A-4C, in embodiments, the one or more pins may be bent or curved so that portions of the pins may be located inside or outside of a relative footprint or boundary defined by the one or more recesses. In one embodiment, the pins of the bottom component may be located within a footprint of the recess of the top component. For example, FIG. 4A includes top component 120 mounted over bottom component 110, where solder joint 135 joins pins 115 of bottom component 110 to recesses 125 of top component 120. In further reference to FIG. 4A, pins 115 are located within a footprint, f, of recesses 125. In another embodiment, a bottom portion of the pins may be located within a footprint of the recess, whereas a top portion of the pins may be located outside of the footprint of the recess. For example, FIG. 4B includes top component 120 mounted over bottom component 110, where solder joint 135 joins pins 115 of bottom component 110 to recesses 125 of top component 120. In further reference to FIG. 4B, bottom portion 115B of pins 115 (e.g., the portion of the pins joined to the bottom component 110) are located within a footprint, f, of recesses 125, whereas top portion 115A of pins 115 are located outside of footprint, f, of recesses 125. In another embodiment, both a bottom portion and a top portion of the pins may be located outside of the footprint of the recess. For example, FIG. 4C includes top component 120 mounted over bottom component 110, where solder joint 135 joins pins 115 of bottom component 110 to recesses 125 of top component 120. In further reference to FIG. 4C, bottom portion 115B of pins 115 and top portion 115A are located outside of footprint, f, of recesses 125. It should be noted that where a top portion of the pins bend or curve directly over a top surface of top component 120 as described in the examples of FIGS. 4B-4C (such as directly over top pads 123 of the liner layer), such top portions may act to prevent solder material from flowing down through the through hole (or half hole) of the recesses during the soldering process.

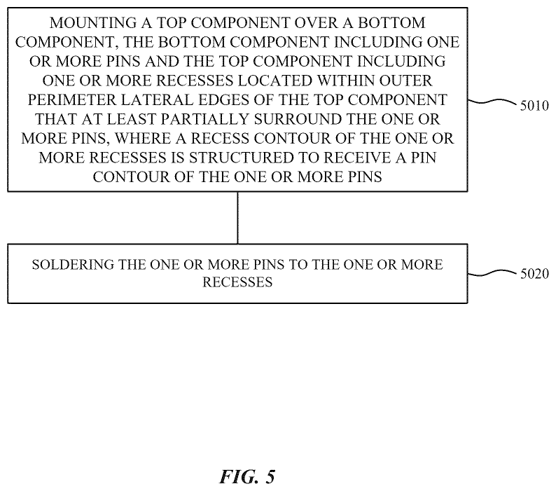

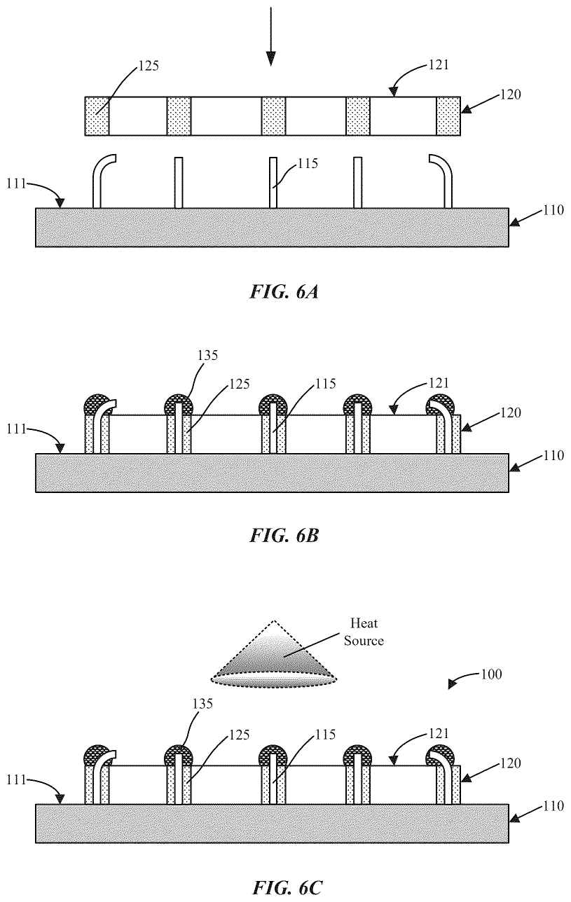

Referring now to FIGS. 5 and 6A-C, FIG. 5 is a flow chart and FIGS. 6A-6C are schematic cross-sectional side view illustrations of a method for joining a bottom component and a top component in accordance with embodiments. In the interest of clarity and conciseness, the method of FIG. 5 is described concurrently with the illustrations of FIGS. 6A-6C. As shown in FIG. 6A, the process sequence can begin at operation 5010 where top component 120 may be mounted over bottom component 110, where the one or more recesses of top component 120 align with the one or more pins of bottom component 110. Pins 115 extend vertically from top surface 111 of bottom component 110 and protrude above top surface 121 of top component 120. In addition, pins 115 of bottom component 110 and recesses 125 top component 120 may be structured so that the shape or contour of pins 115 sufficiently match the shape or contour of recesses 125. Further, pins 115 of bottom component 110 and recesses 125 of top component 120 may be structured so that the size of pins 115 (e.g., diameter, width, etc.) is less than the size of recesses 125 (e.g., diameter, width, etc.) in order for recesses 125 to at least partially surround pins 115.

At operation 5020, the one or more pins may be soldered to the one or more recesses. In one embodiment, the solder material (e.g., solder balls) may be melted by a light source (e.g., laser light) and then deposited or jetted into the proper soldering position (e.g., laser solder jetting). In another embodiment, the solder material may be melted on a thermal tip of a soldering device (e.g., soldering iron) and then transferred to the proper soldering position. In another embodiment still, the soldering material may be deposited first and then heated, as illustrated in FIGS. 6B-6C. For example, in reference to FIG. 6B, solder material may be deposited where pins 115 protrude above top surface 121 of top component 120. The solder material may include metal alloys such as tin/lead, tin-zinc, tin/silver, etc. As illustrated in the example of FIG. 6B, top portion 115A of pins 115 bend or curve over top surface 121 of top component 120. In this way, top portion 115A of pins 115 prevents the solder material from flowing down the through hole (or half hole) of recesses 125. In reference to FIG. 6C, a heat source (e.g., laser light, etc.) may be applied to melt solder material, which may then solidify upon removal of the heat source and form solder joint 135. In an embodiment, the heat source applied may include a laser light or beam as part of a laser soldering process, although other soldering processes are contemplated.

In utilizing the various aspects of the embodiments, it would become apparent to one skilled in the art that combinations or variations of the above embodiments are possible for solder bonding multiple components of an electronic package. Although the embodiments have been described in language specific to structural features and/or methodological acts, it is to be understood that the appended claims are not necessarily limited to the specific features or acts described. The specific features and acts disclosed are instead to be understood as embodiments of the claims useful for illustration.

What is claimed is:

1. An electronic assembly comprising:
a bottom component, wherein the bottom component includes one or more pins;
a top component mounted over the bottom component, the top component including one or more recesses located within outer perimeter lateral edges of the top component that at least partially surround the one or more pins, wherein a recess contour of the one or more recesses is structured to receive a pin contour of the one or more pins; and
one or more solder joints that connect the one or more pins to the one or more recesses.

2. The electronic assembly of claim 1, wherein the bottom component is an electronic component.

3. The electronic assembly of claim 2, wherein the electronic component is an optical module.

4. The electronic assembly of claim 2, wherein the electronic component is a chip driver.

5. The electronic assembly of claim 1, wherein the one or more pins include electroless nickel immersion gold plating.

6. The electronic assembly of claim 1, wherein the one or more pins include tin coating.

7. The electronic assembly of claim 1, wherein the one or more pins extend vertically from a top surface of the bottom component.

8. The electronic assembly of claim 1, wherein the one or more pins are circular cylinders.

9. The electronic assembly of claim 1, wherein the one or more pins are elliptic cylinders.

10. The electronic assembly of claim 1, wherein a top portion of the one or more pins curves over a top surface of the top component.

11. The electronic assembly of claim 1, wherein the top component is a printed circuit board.

12. The electronic assembly of claim 11, wherein the printed circuit board is rigid.

13. The electronic assembly of claim 11, wherein the printed circuit board is flexible.

14. The electronic assembly of claim 1, further including an electric module connected to the top component.

15. The electronic assembly of claim 14, wherein the electric module is a battery.

16. The electronic assembly of claim 1, wherein the one or more recesses are c-shaped.

17. The electronic assembly of claim 1, wherein the one or more recesses are u-shaped.

18. A method for joining components comprising:
mounting a top component over a bottom component, the bottom component including one or more pins, and the top component including one or more recesses located within outer perimeter lateral edges of the top component that at least partially surround the one or more pins, wherein a recess contour of the one or more recesses is structured to receive a pin contour of the one or more pins; and
soldering the one or more pins to the one or more recesses.

19. The method of claim 18, wherein soldering the one or more pins to the one or more recesses includes applying heat to a solder material in a laser soldering process.

20. The method of claim 18, wherein a top portion of the one or more pins curves over a top surface of the top component.
